(19) United States
(12) Patent Application Publication
(10) Pub. No.: US 2026/0032983 A1
(43) Pub. Date: Jan. 29, 2026

(54) INTEGRATED CIRCUIT DEVICE

(71) Applicant: Samsung Electronics Co., Ltd., Suwon-si (KR)

(72) Inventors: Geon-beom Lee, Suwon-si (KR); Doyun Kim, Suwon-si (KR); Jongwon Lee, Suwon-si (KR); Taiuk Rim, Suwon-si (KR); Soyoung Jo, Suwon-si (KR); Kyosuk Chae, Suwon-si (KR)

(21) Appl. No.: 19/023,507

(22) Filed: Jan. 16, 2025

(30) Foreign Application Priority Data
Jul. 29, 2024 (KR) 10-2024-0100552

(51) Int. Cl. H10D 64/27; H10B 12/00; H10D 64/66; H10D 64/68

(52) U.S. Cl. CPC H10D 64/513; H10B 12/488; H10D 64/661; H10D 64/691

(57) ABSTRACT

An integrated circuit device includes a substrate having a word line trench formed therein, a gate insulating film covering an inner surface of the word line trench, a first gate pattern filling a lower region of the word line trench on the gate insulating film, an interface barrier film disposed on the first gate pattern, an intermediate insulating film covering the interface barrier film and a side surface of the gate insulating film, the side surface being higher than the upper surface of the interface barrier film relative to a lower surface of the substrate, a second gate pattern filling a middle region of the word line trench on the intermediate insulating film, an insulating capping pattern filling an upper region of the word line trench on the second gate pattern, and an oxide film covering a lower surface and side surfaces of the insulating capping pattern.

### CROSS-REFERENCE TO RELATED APPLICATIONS

This application is based on and claims priority under 35 U.S.C. § 119 to Korean Patent Application No. 10-2024-0100552, filed on Jul. 29, 2024, in the Korean Intellectual Property Office, the disclosure of which is incorporated by reference herein in its entirety.

### BACKGROUND

The inventive concept relates to an integrated circuit device, and more particularly, to an integrated circuit device having a buried line.

With the recent rapid development of miniaturized semiconductor process technology, the area of unit cells is decreasing as the integration of integrated circuit devices is accelerating. Therefore, the area that a capacitor may occupy within a unit cell is also decreasing. For example, as the integration level of integrated circuit devices such as dynamic random-access memory (DRAM) increases, the area of the unit cells decreases, while the required electrostatic capacitance is maintained or is increasing. Accordingly, there is a need for a structure that can overcome spatial limitations and design rule limitations in capacitors, improve capacitance, and maintain desired electrical characteristics.

In the case of a buried channel array transistor (BCAT) which is arranged in a memory cell area of an integrated circuit device, a gate electrode is buried in a substrate to reduce the short channel effect.

### SUMMARY

The inventive concept provides an integrated circuit device in which a buried channel array transistor (BCAT) disconnection phenomenon is addressed, and which has improved electrical characteristics such as improved refresh characteristics.

The problem to be solved by the inventive concept is not limited to the problems above, and other benefits will be clearly understood by those skilled in the art from the description below.

According to an aspect of the inventive concept, there is provided an integrated circuit device including a substrate having a word line trench formed therein, a gate insulating film covering an inner surface of the word line trench, a first gate pattern filling a lower region of the word line trench on the gate insulating film, an interface barrier film disposed on the first gate pattern, an intermediate insulating film covering an upper surface of the interface barrier film and a side surface of the gate insulating film, the side surface of the gate insulating film being higher than the upper surface of the interface barrier film relative to a lower surface of the substrate, a second gate pattern filling a middle region of the word line trench on the intermediate insulating film, an insulating capping pattern filling an upper region of the word line trench on the second gate pattern, and an oxide film covering a lower surface and side surfaces of the insulating capping pattern.

According to another aspect of the inventive concept, there is provided an integrated circuit device including a substrate having a word line trench formed therein, a gate insulating film covering an inner surface of the word line trench, a first gate pattern filling a lower region of the word line trench on the gate insulating film, an interface barrier film disposed on the first gate pattern, an intermediate insulating film covering an upper surface of the interface barrier film and a side surface of the gate insulating film, the side surface of the gate insulating film being higher than the upper surface of the interface barrier film relative to a lower surface of the substrate, a second gate pattern filling a middle region of the word line trench on the intermediate insulating film, an insulating capping pattern filling an upper region of the word line trench on the second gate pattern, and an oxide film disposed between the insulating capping pattern and the second gate pattern.

According to another aspect of the inventive concept, there is provided an integrated circuit device including a substrate having a word line trench formed therein, a gate insulating film covering an inner surface of the word line trench, a first gate pattern filling a lower region of the word line trench on the gate insulating film, an interface barrier film disposed on the first gate pattern, an intermediate insulating film covering an upper surface of the interface barrier film and a side surface of the gate insulating film, the side surface of the gate insulating film being higher than the upper surface of the interface barrier film relative to a lower surface of the substrate, a second gate pattern filling a middle region of the word line trench on the intermediate insulating film, an insulating capping pattern filling an upper region of the word line trench on the second gate pattern, an oxide film covering a lower surface and side surfaces of the insulating capping pattern, and a pair of source/drain regions formed outside on opposite sides of the word line trench, wherein the intermediate insulating film includes a horizontal extension portion arranged between the upper surface of the interface barrier film and a lower surface of the second gate pattern, and a vertical extension portion arranged on the gate insulating film to be in contact with side surfaces of the second gate pattern, the vertical extension portion extends from the upper surface of the interface barrier film to an upper portion of the word line trench, and upper surfaces of the vertical extension portion are disposed on a same plane as an upper surface of the insulating capping pattern, the oxide film includes a first portion arranged between an upper surface of the second gate pattern and the lower surface of the insulating capping pattern, and a second portion extending vertically along the side surfaces of the insulating capping pattern, an upper surface of the second portion is arranged on a same plane as the upper surface of the insulating capping pattern, the first gate pattern includes a metal or a conductive metal nitride, the second gate pattern includes polysilicon, the interface barrier film includes a nitride of a metal material included in the first gate pattern, and a lower surface of the pair of source/drain regions are arranged higher than an upper surface of the second gate pattern relative to the lower surface of the substrate.

### BRIEF DESCRIPTION OF THE DRAWINGS

Embodiments will be more clearly understood from the following detailed description taken in conjunction with the accompanying drawings in which:

FIG. 1 is a layout diagram illustrating an integrated circuit device according to an embodiment;

FIG. 2 is an enlarged schematic layout diagram to describe some components of a memory cell area of FIG. 1;

FIG. 3 is a cross-sectional view of a portion of FIG. 2 taken along line A-A′ of FIG. 2 showing some components of the memory cell area;

FIG. 4 is an enlarged cross-sectional view of region EX1 of FIG. 3;

FIG. 5 is a cross-sectional view of an integrated circuit device according to an embodiment;

FIG. 6 is a cross-sectional view of an integrated circuit device according to an embodiment;

FIG. 7 is a cross-sectional view of an integrated circuit device according to an embodiment;

FIGS. 8 to 15 are cross-sectional views an integrated circuit device stages in different states in a method of manufacturing an integrated circuit device, according to an embodiment; and

FIGS. 16 to 18 are cross-sectional views illustrating an integrated circuit device stages in different states in a method of manufacturing an integrated circuit device, according to an embodiment.

### DETAILED DESCRIPTION OF THE EMBODIMENTS

Hereinafter, embodiments will be described in detail with reference to the attached drawings. The invention may, however, be embodied in many different forms and should not be construed as limited to the example embodiments set forth herein. It should also be emphasized that the disclosure provides details of alternative examples, but such listing of alternatives is not exhaustive. Furthermore, any consistency of detail between various examples should not be interpreted as requiring such detail. The language of the claims should be referenced in determining the requirements of the invention.

The same reference numerals are used for the same or similar components in the drawings, and repeated descriptions of these may omitted. Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, components described as being “electrically connected” are configured such that an electrical signal can be transferred from one component to the other (although such electrical signal may be attenuated in strength as it is transferred and may be selectively transferred). Moreover, components that are “directly electrically connected” form a common electrical node through electrical connections by one or more conductors, such as, for example, wires, pads, internal electrical lines, through vias, etc. As such, directly electrically connected components do not include components electrically connected through active elements, such as transistors or diodes.

Terms such as “same,” “equal,” “planar,” “coplanar,” “parallel,” and “perpendicular,” as used herein encompass identicality or near identicality including variations that may occur resulting from conventional manufacturing processes. The term “substantially” may be used herein to emphasize this meaning, unless the context or other statements indicate otherwise.

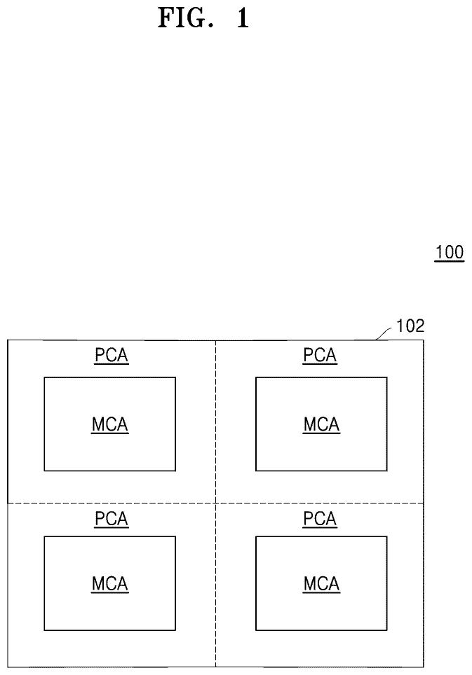

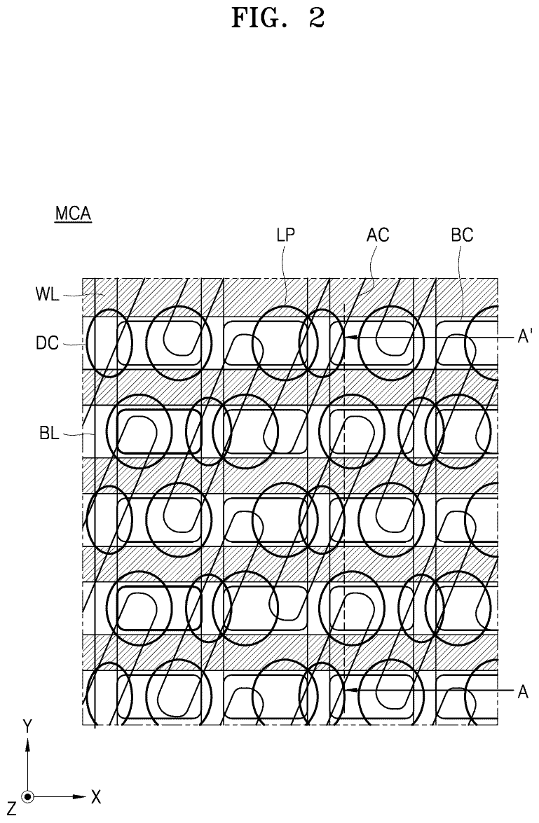

FIG. 1 is a layout diagram illustrating an integrated circuit device according to an embodiment. FIG. 2 is an enlarged schematic layout diagram to describe some components of a memory cell area of FIG. 1.

Referring to FIGS. 1 and 2, an integrated circuit device 100 may include a substrate 102 including a cell array area MCA and a peripheral circuit area PCA. In some embodiments, the cell array area MCA may be a memory cell area of a dynamic random-access memory (DRAM) device, and the peripheral circuit area PCA may be a core area or a peripheral circuit area of the DRAM device. For example, the peripheral circuit area PCA may include peripheral circuit transistors (not shown) for transmitting signals and/or power to a memory cell array included in the cell array area MCA. In embodiments, a peripheral circuit transistor (not shown) may configure various circuits such as a command decoder, control logic, address buffer, row decoder, column decoder, sense amplifier, and data input/output circuit.

As illustrated in FIG. 2, the integrated circuit device 100 may include a plurality of active regions AC arranged to extend obliquely with respect to a first horizontal direction (X-direction) and a second horizontal direction (Y-direction) on an XY plane. A plurality of word lines WL may extend in the first horizontal direction (X-direction) across the plurality of active areas AC. Each of the plurality of word lines WL may have a substantially constant width or a constant width in the first horizontal direction (X-direction), which is a longitudinal direction of the word lines WL.

A plurality of bit lines BL may be parallel to each other in the second horizontal direction (Y-direction) and extend in the first horizontal direction (X-direction) over the plurality of word lines WL. The plurality of bit lines BL may be connected to the plurality of active areas AC via direct contacts DC. A plurality of cell transistors (not shown) may be arranged at intersection points between the plurality of word lines WL and the plurality of bit lines BL. A plurality of cell capacitors (not shown) may be arranged on the plurality of cell transistors, respectively.

A plurality of buried contacts BC may be arranged between two adjacent bit lines BL among the plurality of bit lines BL. A plurality of conductive landing pads LP may be arranged on the plurality of buried contacts BC. The plurality of buried contacts BC and the plurality of conductive landing pads LP may connect a lower electrode (not shown) of a capacitor formed on the plurality of bit lines BL, to the active areas AC. The plurality of conductive landing pads LP may be respectively arranged to at least partially overlap with the buried contacts BC.

According to embodiments, the plurality of word lines WL may be buried within the substrate 102, and the integrated circuit device 100 may include a buried channel array transistor (BCAT) structure.

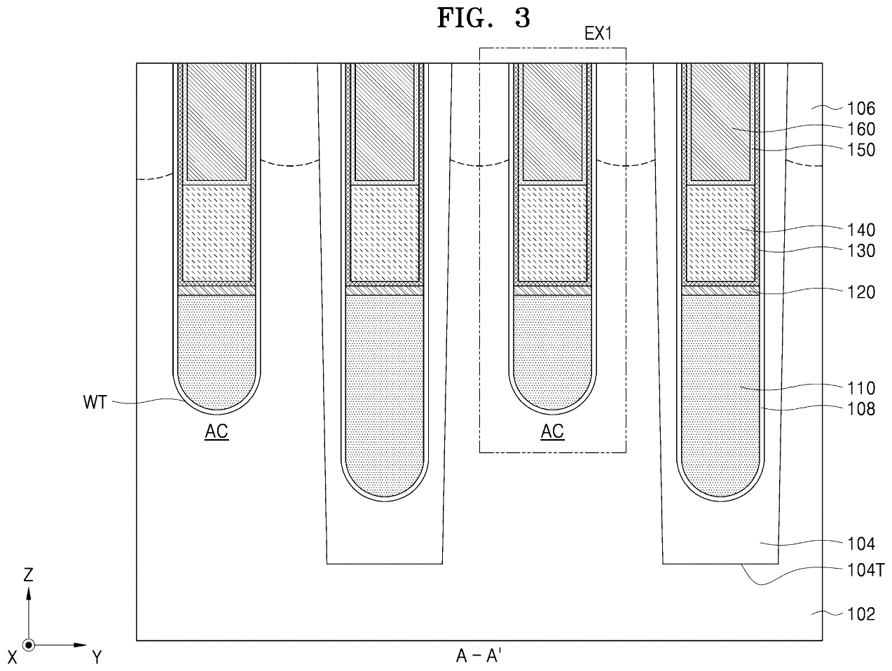

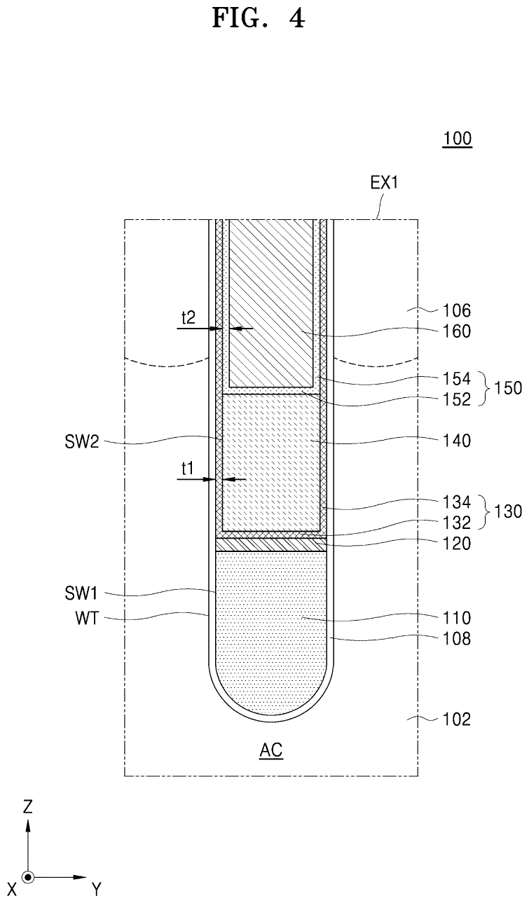

FIG. 3 is a cross-sectional view of some components taken along line A-A′ of FIG. 2. FIG. 4 is an enlarged cross-sectional view of region EX1 of FIG. 3.

Referring to FIGS. 3 and 4, the integrated circuit device 100 includes the substrate 102 having a device isolation trench 104T formed therein. The device isolation trench 104T may be filled with a device isolation film 104. The plurality of active areas AC may be defined on the substrate 102 by the device isolation trench 104T and the device isolation film 104.

The device isolation film 104 may surround the plurality of active areas AC on the substrate 102. The device isolation film 104 may include a silicon oxide film, a silicon nitride film, or a combination thereof.

The substrate 102 may include silicon, for example, single crystal silicon, polycrystalline silicon, or amorphous silicon. In other embodiments, the substrate 102 may include a semiconductor, such as Si or Ge, or a compound semiconductor, such as SiGe, SiC, GaAs, InAs, InGaAs, or InP. In embodiments, the substrate 102 may include a conductive region, such as a dopant-doped well, or a dopant-doped structure.

A plurality of word line trenches WT extending parallel to each other in the first horizontal direction (X-direction) may be formed in the substrate 102. Each of the plurality of word line trenches WT may have a line shape extending in the first horizontal direction (X-direction) across the plurality of active areas AC and the device isolation film 104. Each of the plurality of word line trenches WT may be filled with a gate insulating film 108, a first gate pattern 110, an interface barrier film 120, an intermediate insulating film 130, a second gate pattern 140, an oxide film 150, and an insulating capping pattern 160.

In each of the plurality of word line trenches WT, a vertical level of a bottom surface of the word line trench WT on the plurality of active regions AC may be higher than a vertical level of a bottom surface of the word line trench WT on the device isolation film 104 (e.g., higher relative to a lower surface of the substrate 102).

The gate insulating film 108 may conformally cover an inner surface of the word line trench WT so as to be in contact with the plurality of active regions AC and the device isolation film 104. The gate insulating film 108 may include a silicon oxide film, for example, a SiO₂ film.

The first gate pattern 110 may fill a lower region of the word line trench WT, which is a portion of the word line trench WT, on the gate insulating film 108 and extend in the first horizontal direction (X-direction). The first gate pattern 110 may have a pair of side walls SW1 that are opposite to each other in the second horizontal direction (Y-direction) and each contact the gate insulating film 108. The first gate pattern 110 may have a structure that fills the word line trench WT between the pair of sidewalls SW1 without interruption in the second horizontal direction (Y-direction). Among surfaces of the first gate pattern 110, the surfaces with the exception of an upper surface of the first gate pattern 110, which is in contact with a lower surface of the interface barrier film 120, may be in contact with the gate insulating film 108.

In embodiments, the first gate pattern 110 may include a metal or a conductive metal nitride. For example, the first gate pattern 110 may include titanium (Ti), titanium nitride (TiN), tantalum (Ta), tantalum nitride (TaN), tungsten (W), tungsten nitride (WN), or the like.

The interface barrier film 120 may be arranged on the first gate pattern 110. The interface barrier film 120 may cover the upper surface of the first gate pattern 110 and extend in the first horizontal direction (X-direction) within the word line trench WT. In some embodiments, the interface barrier film 120 may have a width equal to the width between the pair of sidewalls SW1 of the first gate pattern 110 and completely cover the upper surface of the first gate pattern 110.

The interface barrier film 120 may include a metal nitride formed by nitriding the upper surface of the first gate pattern 110. For example, the interface barrier film 120 may include titanium nitride. In some embodiments, the interface barrier film 120 may be included in the upper surface of the first gate pattern 110.

The interface barrier film 120 may be disposed between the first gate pattern 110 and the second gate pattern 140. With the interface barrier film 120 included between the first gate pattern 110 and the second gate pattern 140, reaction or mixing between the first gate pattern 110 and the second gate pattern 140 may be prevented. In addition, the interface barrier film 120 may prevent oxygen from diffusing into the first gate pattern 110 during a subsequent thermal process and prevent precipitation of the first gate pattern 110.

The intermediate insulating film 130 may be arranged on an upper surface of the interface barrier film 120. The intermediate insulating film 130 may be formed along a surface of the gate insulating film 108, the surface being higher than the upper surface of the interface barrier film 120, and along the interface barrier film 120.

The intermediate insulating film 130 may include a horizontal extension portion 132 disposed on the upper surface of the interface barrier film 120 and a vertical extension portion 134, which may be referred to as a pair of vertical extension portions 134 to emphasize that the vertical extension portion 134 is on a pair of surfaces, disposed on the gate insulating film 108. Hereafter, a portion of an object may be referred to as a plurality of portions (e.g., pair of portions) to emphasize that the portion may be divided into multiple sub-portions. The horizontal extension portion 132 may cover the upper surface of the interface barrier film 120 and extend in the first horizontal direction (X-direction) within the word line trench WT. In some embodiments, the horizontal extension portion 132 may have a width equal to the width between the pair of sidewalls SW1 of the first gate pattern 110 and completely cover the upper surface of the interface barrier film 120.

The pair of vertical extension portions 134 may be respectively connected to both ends (e.g., opposite ends) of the horizontal extension portion 132. Each vertical extension portion 134 may extend in a vertical direction (Z-direction) along a surface of the gate insulating film 108. The vertical extension portion 134 may extend from the upper surface of the interface barrier film 120 to an upper portion of the word line trench WT. The vertical extension portion 134 may extend in the vertical direction (Z-direction) such that an upper surface of the vertical extension portion 134 is arranged on the same plane as an upper surface of the insulating capping pattern 160.

The intermediate insulating film 130 may be formed by depositing an insulator in a space formed by the interface barrier film 120 and the gate insulating film 108. In some embodiments, the intermediate insulating film 130 may be formed to conformally cover the upper surface of the interface barrier film 120 and the surface of the gate insulating film 108. For example, a thickness t1 of the intermediate insulating film 130 may be about 5 Å to about 30 Å, or may be between 5 Å and 30 Å.

In some embodiments, the intermediate insulating film 130 may be an insulator including a film material including at least one of ZnO, Al₂O₃, TiO₂, or a combination of thin films. The intermediate insulating film 130 may be between the first gate pattern 110 and the second gate pattern 140, and reduce the contact resistance between the first gate pattern 110 and the second gate pattern 140. The intermediate insulating film 130 may reduce the BCAT disconnection phenomenon by reducing the contact resistance of a word line formed by the first gate pattern 110 and the second gate pattern 140.

The second gate pattern 140 may fill a middle region of the word lines trench WT, which is a portion of the word line trench WT, on the intermediate insulating film 130, and extend in the first horizontal direction (X-direction). The second gate pattern 140 may have a pair of side walls SW2 that are opposite to each other in the second horizontal direction (Y-direction) and each contact the intermediate insulating film 130. The second gate pattern 140 may have a structure that fills the word line trench WT between the pair of sidewalls SW2 without interruption in the second horizontal direction (Y-direction). Among the surfaces of the second gate pattern 140, other surfaces except an upper surface of the second gate pattern 140, the surface being in contact with a lower surface of the oxide film 150, may be in contact with the intermediate insulating film 130.

In embodiments, the second gate pattern 140 may include polysilicon. In some embodiments, the second gate pattern 140 may include polysilicon doped with impurities. For example, the second gate pattern 140 may be doped with an impurity of the same conductivity type as an impurity doped in a pair of source/drain regions 106.

The first gate pattern 110 and the second gate pattern 140 that overlap each other in the vertical direction (Z-direction) may form a double word line.

The oxide film 150 may be arranged on the upper surface of the second gate pattern 140. The oxide film 150 may be formed along a surface of the gate insulating film 108, the surface being higher than the upper surface of the second gate pattern 140, and the upper surface of the second gate pattern 140 (e.g., higher with reference to a lower surface of the substrate 102). The oxide film 150 may be formed to cover a lower surface and side surfaces of the insulating capping pattern 160.

The oxide film 150 may include a first portion 152 disposed on the upper surface of the second gate pattern 140 and a pair of second portions 154 disposed on the vertical extension portions 134 of the intermediate insulating film 130. The first portion 152 may cover the upper surface of the second gate pattern 140 and extend in the first horizontal direction (X-direction) within the word line trench WT. In some embodiments, the first portion 152 may have a width equal to the width between the pair of sidewalls SW2 of the second gate pattern 140 and completely cover the upper surface of the second gate pattern 140.

The pair of second portions 154 may be respectively connected to both ends (e.g., opposite ends) of the first portion 152. Each second portion 154 may extend in the vertical direction (Z-direction) along an inner surface of the vertical extension portion 134 of the intermediate insulating film 130. The second portions 154 may extend from the upper surface of the second gate pattern 140 to an upper portion of the word line trench WT. The second portions 154 may extend in the vertical direction (Z-direction) such that the upper surface of the second portion 154 is arranged on the same plane as the upper surface of the insulating capping pattern 160.

The oxide film 150 may be formed through an oxidation process. In some embodiments, the oxide film 150 may include silicon oxide. For example, the oxide film 150 may include SiO₂ or amorphous SiOₓ. In some embodiments, the oxide film 150 may be formed to conformally cover the upper surface of the second gate pattern 140 and the inner surface of the vertical extension portions 134 of the intermediate insulating film 130. For example, a thickness t2 of the oxide film 150 may be about 5 Å to about 40 Å, or may be between 5 Å and 40 Å.

By forming the oxide film 150 on top of the second gate pattern 140, phosphorus out-diffusion within the second gate pattern 140 may be suppressed in a subsequent thermal process. As the oxide film 150 suppresses phosphorus out-diffusion of the second gate pattern 140, the concentration of polysilicon in the second gate pattern 140 increases. The increased concentration of polysilicon has a function of reducing leakage current by reducing the electric field when a device is not operating. Furthermore, due to a film located in the second portions 154, the electric field is further reduced, further reducing leakage current and thereby also reducing the power consumption of the device.

If oxygen gas diffuses into the first gate pattern 110 during an oxidation process to form the oxide film 150, the first gate pattern 110 may be precipitated, causing a BCAT disconnection phenomenon. However, the interface barrier film 120 may prevent oxygen from diffusing into the first gate pattern 110, thereby addressing the BCAT disconnection phenomenon.

The insulating capping pattern 160 may fill an upper region of the word line trench WT on the second gate pattern 140 and extend in the first horizontal direction (X-direction). The lower surface and the side surfaces of the insulating capping pattern 160 may be formed to be surrounded by the oxide film 150. In embodiments, the insulating capping pattern 160 may include a silicon nitride film, a silicon oxynitride film, or a combination thereof.

As described above, a gate structure including the gate insulating film 108, the first gate pattern 110, the interface barrier film 120, the intermediate insulating film 130, the second gate pattern 140, the oxide film 150, and the insulating capping pattern 160 may be provided in the word line trench WT.

In the plurality of active regions AC, the pair of source/drain regions 106 may be arranged in an upper portion of the substrate 102 on both sides (e.g., opposite sides) of the gate structure. The pair of source/drain regions 106 may be located in a portion of the substrate 102 adjacent to upper sidewalls of the word line trench WT. In embodiments, the pair of source/drain regions 106 may be positioned higher than the upper surface of the second gate pattern 140 (e.g., higher relative to a bottom surface of the substrate 102).

The pair of source/drain regions 106 may each be formed as an impurity region including impurity ions implanted into the substrate 102. In embodiments, circuits may be connected to the pair of source/drain regions 106. For example, if the integrated circuit device 100 is a DRAM device, a capacitor may be connected to one of the pair of source/drain regions 106 and a bit line may be connected to the other of the pair of source/drain regions 106.

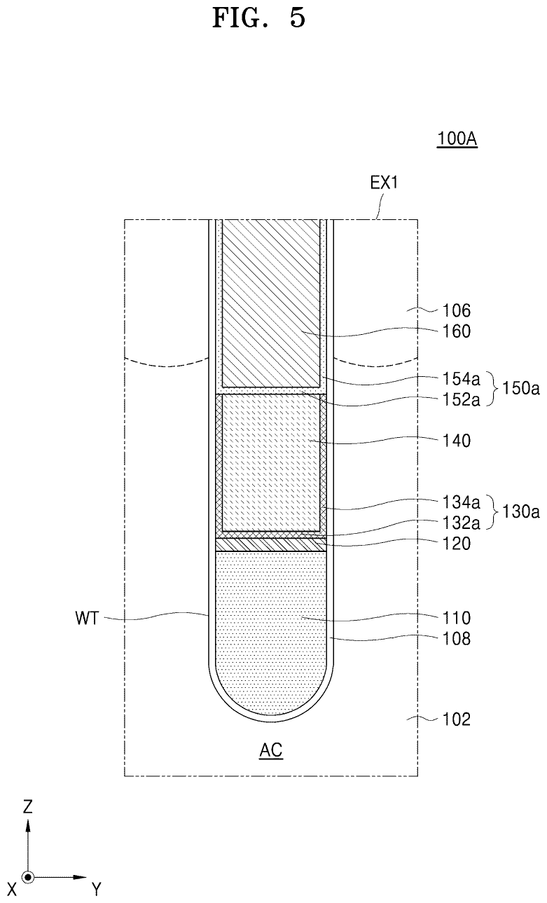

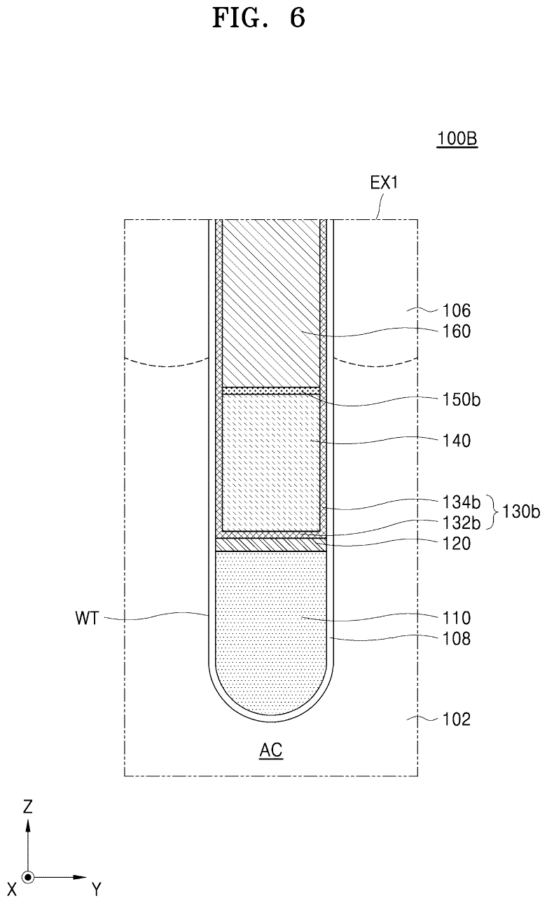

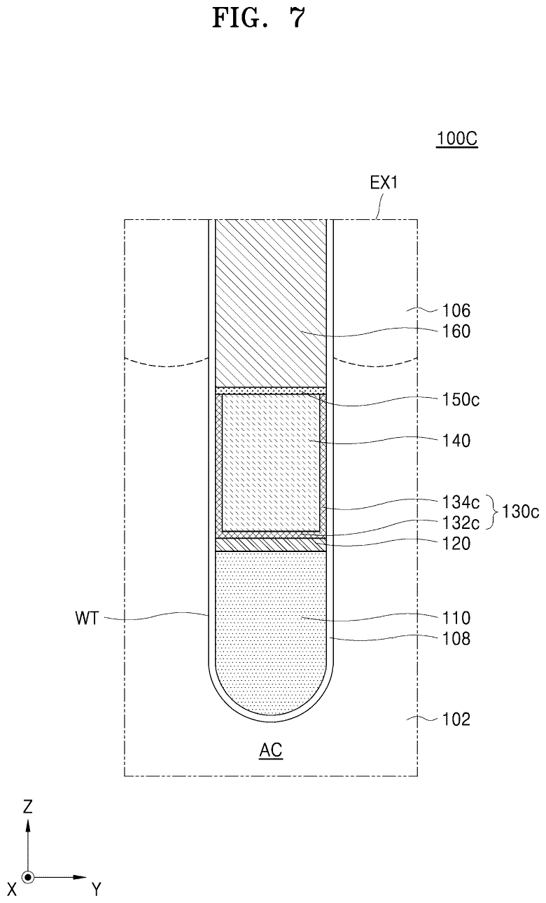

FIG. 5 is a cross-sectional view to describe an integrated circuit device 100A according to an embodiment. FIG. 6 is a cross-sectional view to describe an integrated circuit device 100B according to an embodiment. FIG. 7 is a cross-sectional view to describe an integrated circuit device 100C according to an embodiment.

The integrated circuit devices 100A, 100B, 100C of FIGS. 5 to 7 are the same as or substantially similar to the integrated circuit device 100 illustrated in FIG. 4, except that the shapes of the intermediate insulating film 130 and the oxide film 150 are different. Therefore, with reference to FIG. 4, the description of the components already described may be omitted or simplified.

Referring to FIG. 5, the inside of the word line trench WT may be filled with the gate insulating film 108, the first gate pattern 110, the interface barrier film 120, an intermediate insulating film 130a, the second gate pattern 140, an oxide film 150a, and the insulating capping pattern 160.

The gate insulating film 108 may conformally cover the inner surface of the word line trench WT. The first gate pattern 110 may fill a lower region of the word line trench WT, which is a portion of the word line trench WT, on the gate insulating film 108, and may extend in the first horizontal direction (X-direction). The interface barrier film 120 may be arranged on the first gate pattern 110.

The intermediate insulating film 130a may be arranged on the upper surface of the interface barrier film 120. The intermediate insulating film 130a may include a horizontal extension portion 132a disposed on the upper surface of the interface barrier film 120 and a pair of vertical extension portions 134a disposed on the gate insulating film 108.

The pair of vertical extension portions 134a may be respectively connected to both ends (e.g., opposite ends) of the horizontal extension portion 132a. Each vertical extension portion 134a may extend in the vertical direction (Z-direction) along the surface of the gate insulating film 108 such that upper surfaces of the vertical extension portion 134a are arranged on the same plane as the upper surface of the second gate pattern 140. For example, the vertical extension portions 134a may extend in the vertical direction (Z-direction) along the sidewalls SW1 of the second gate pattern 140 and not extend higher than the upper surface of the second gate pattern 140.

The second gate pattern 140 may be formed to fill the inside of the intermediate insulating film 130a.

The oxide film 150a may be arranged on the upper surface of the second gate pattern 140 and an upper surface of the intermediate insulating film 130a. The oxide film 150 may include a first portion 152a disposed on the upper surfaces of the second gate pattern 140 and the intermediate insulating film 130a, and a pair of second portions 154a disposed on the gate insulating film 108. The pair of second portions 154a may be respectively connected to both ends (e.g., opposite ends) of the first portion 152a. The second portions 154a may extend in the vertical direction (Z-direction) such that upper surfaces of the second portion 154a are arranged on the same plane as the upper surface of the insulating capping pattern 160.

The insulating capping pattern 160 may fill an upper region of the word line trench WT on the second gate pattern 140 and extend in the first horizontal direction (X-direction) (e.g., may extend lengthwise). The lower surface and the side surfaces of the insulating capping pattern 160 may be formed to be surrounded by the oxide film 150. Since the vertical extension portion 134a of the intermediate insulating film 130a extends only to the upper surface of the second gate pattern 140, the side surfaces of the insulating capping pattern 160 may come into contact with the gate insulating film 108 with the oxide film 150 therebetween.

Referring to FIG. 6, the inside of the word line trench WT may be filled with the gate insulating film 108, the first gate pattern 110, the interface barrier film 120, an intermediate insulating film 130b, the second gate pattern 140, an oxide film 150b, and the insulating capping pattern 160.

The gate insulating film 108 may conformally cover the inner surface of the word line trench WT. The first gate pattern 110 may fill a lower region of the word line trench WT, which is a portion of the word line trench WT, on the gate insulating film 108, and may extend in the first horizontal direction (X-direction). The interface barrier film 120 may be arranged on the first gate pattern 110.

The intermediate insulating film 130b may be configured similarly to the intermediate insulating film 130 of FIG. 4. The intermediate insulating film 130 may include a horizontal extension portion 132b disposed on the upper surface of the interface barrier film 120 and a pair of vertical extension portions 134b disposed on the gate insulating film 108.

The second gate pattern 140 may fill a middle region of the word line trench WT, which is a portion of the word line trench WT, on the intermediate insulating film 130, and extend in the first horizontal direction (X-direction) (e.g., extend lengthwise).

The oxide film 150 may be arranged on the upper surface of the second gate pattern 140. Compared to FIG. 4, the oxide film 150b may be arranged to completely cover the upper surface of the second gate pattern 140 within the intermediate insulating film 130b, and does not extend along inner surfaces of the vertical extension portion 134b of the intermediate insulating film 130b.

The insulating capping pattern 160 may fill an upper region of the word line trench WT on the second gate pattern 140 and extend in the first horizontal direction (X-direction) (e.g., extend lengthwise). The lower surface of the insulating capping pattern 160 may be in contact with the oxide film 150, and the side surfaces of the insulating capping pattern 160 may be in contact with a portion of the vertical extension portions 134b of the intermediate insulating film 130b.

Referring to FIG. 7, the inside of the word line trench WT may be filled with the gate insulating film 108, the first gate pattern 110, the interface barrier film 120, an intermediate insulating film 130c, the second gate pattern 140, an oxide film 150c, and the insulating capping pattern 160.

The gate insulating film 108 may conformally cover the inner surface of the word line trench WT. The first gate pattern 110 may fill a lower region of the word line trench WT, which is a portion of the word line trench WT, on the gate insulating film 108, and may extend in the first horizontal direction (X-direction). The interface barrier film 120 may be arranged on the first gate pattern 110.

The intermediate insulating film 130c may be configured similarly to the intermediate insulating film 130a of FIG. 5. The intermediate insulating film 130c may include a horizontal extension portion 132c disposed on the upper surface of the interface barrier film 120 and a pair of vertical extension portions 134c disposed on the gate insulating film 108.

The pair of vertical extension portions 134c may be respectively connected to both ends (e.g., opposite ends) of the horizontal extension portion 132c. Each vertical extension portion 134c may extend in the vertical direction (Z-direction) along the surface of the gate insulating film 108 such that upper surfaces of the vertical extension portion 134c are arranged on the same plane as the upper surface of the second gate pattern 140. For example, the vertical extension portions 134c may extend in the vertical direction (Z-direction) along the sidewalls SW1 of the second gate pattern 140 and not extend higher than the upper surface of the second gate pattern 140.

The second gate pattern 140 may be formed to fill the inside of the intermediate insulating film 130c.

The oxide film 150c may be configured similarly to the oxide film 150b of FIG. 6. The oxide film 150c may be arranged to completely cover the upper surface of the second gate pattern 140 within the intermediate insulating film 130b, and does not extend along the inner surface of the vertical extension portions 134b of the intermediate insulating film 130b.

The insulating capping pattern 160 may fill an upper region of the word line trench WT on the second gate pattern 140 and extend in the first horizontal direction (X-direction) (e.g., extend lengthwise). The lower surface of the insulating capping pattern 160 may be in contact with the oxide film 150c, and the side surfaces of the insulating capping pattern 160 may be in contact with the gate insulating film 108.

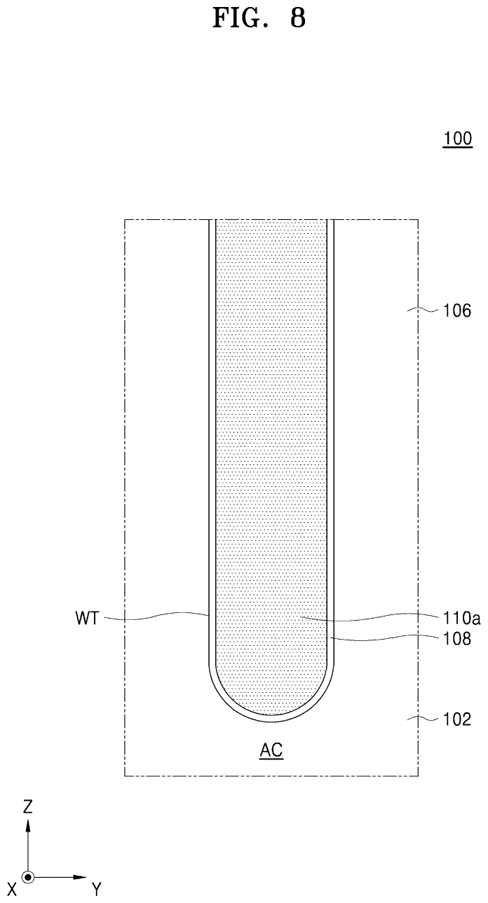

FIGS. 8 to 15 are cross-sectional views illustrating a method of manufacturing an integrated circuit device, according to an embodiment. FIGS. 8 to 15 illustrate a method of manufacturing the integrated circuit device 100 of FIG. 4.

Referring to FIG. 8, the gate insulating film 108 and a first gate film 110a are formed within the word line trench WT of the substrate 102.

The word line trench WT may be formed by forming a hard mask (not shown) on the substrate 102 and etching an upper portion of the substrate 102 by using the hard mask as an etching mask. The gate insulating film 108 is conformally formed on a surface of the word line trench WT. For example, the gate insulating film 108 may include silicon oxide, and the silicon oxide may be formed through a thermal oxidation process or an atomic layer deposition process.

The first gate film 110a is formed on the gate insulating film 108 to fill the word line trench WT. For example, the first gate film 110a may include tungsten nitride.

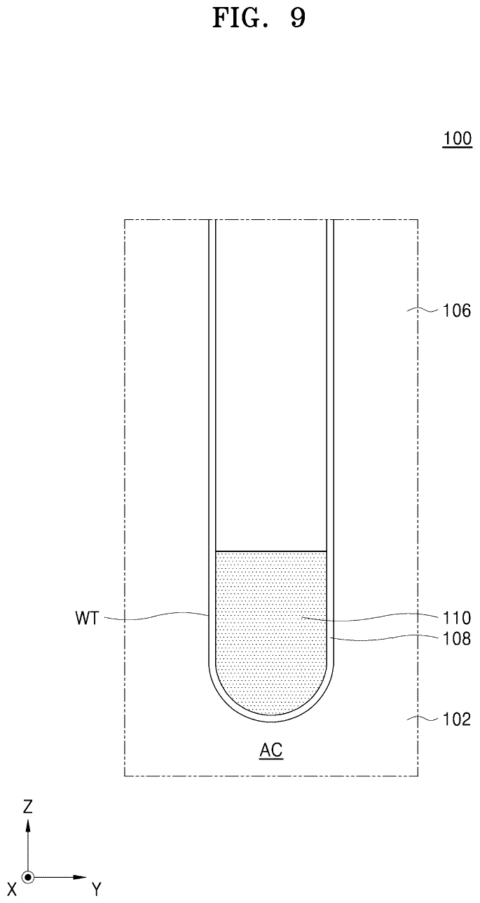

Referring to FIG. 9, a portion of the first gate film 110a is removed through an etch back process to form the first gate pattern 110. In the etch back process, the gate insulating film 108 formed on the sidewalls of the word line trench WT may be hardly etched (e.g., may have relatively little or no material removed). The first gate pattern 110 may be formed on the gate insulating film 108 to fill the lower region of the word line trench WT.

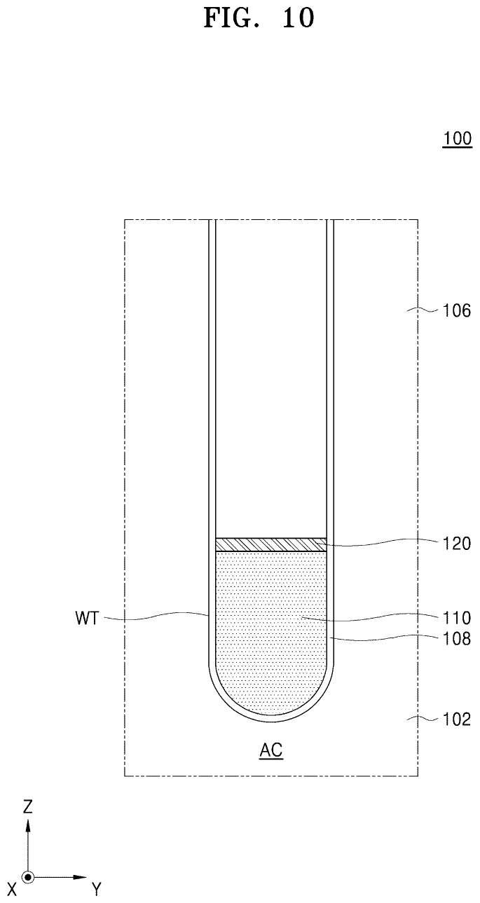

Referring to FIG. 10, the interface barrier film 120 is formed by nitriding the upper surface of the first gate pattern 110. The interface barrier film 120 may be a metal nitride formed by nitriding the upper surface of the first gate pattern 110.

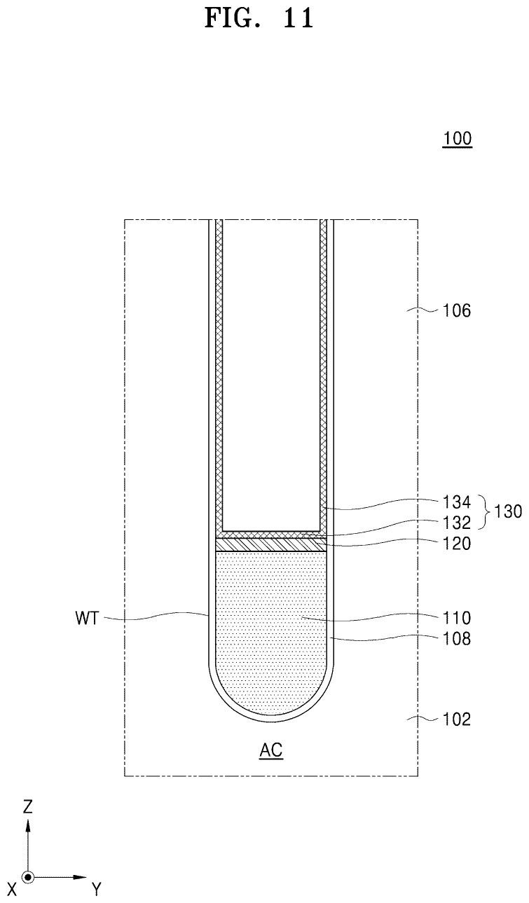

Referring to FIG. 11, the intermediate insulating film 130 is formed along the surface of the gate insulating film 108 and the upper surface of the interface barrier film 120. In embodiments, the intermediate insulating film 130 may be formed through a deposition process. The intermediate insulating film 130 may be conformally formed on the surface of the gate insulating film 108 and the interface barrier film 120.

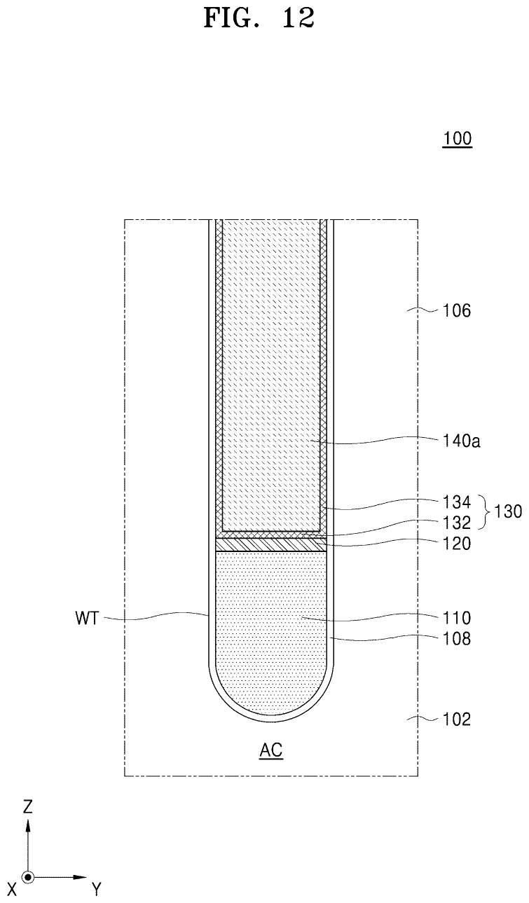

Referring to FIG. 12, the second gate film 140a is formed on the intermediate insulating film 130 to fill the inside of the word line trench WT. In embodiments, the second gate film 140a may be a semiconductor film, such as a polysilicon film doped with impurities. In-situ impurity doping may be performed during a deposition process of a polysilicon film. For example, the impurities doped into the polysilicon film may have the same conductivity as that of the impurities doped into a pair of source/drain regions that are formed subsequently (see 106 in FIG. 4).

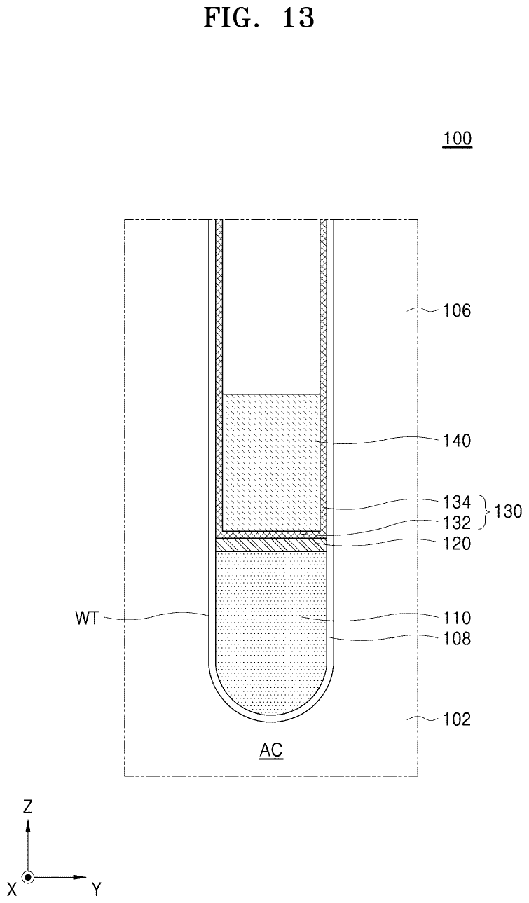

Referring to FIG. 13, a portion of the second gate film (see 140a of FIG. 12) is removed through an etch back process to form the second gate pattern 140. The second gate pattern 140 may be formed on the intermediate insulating film 130 to fill the middle region of the word line trench WT.

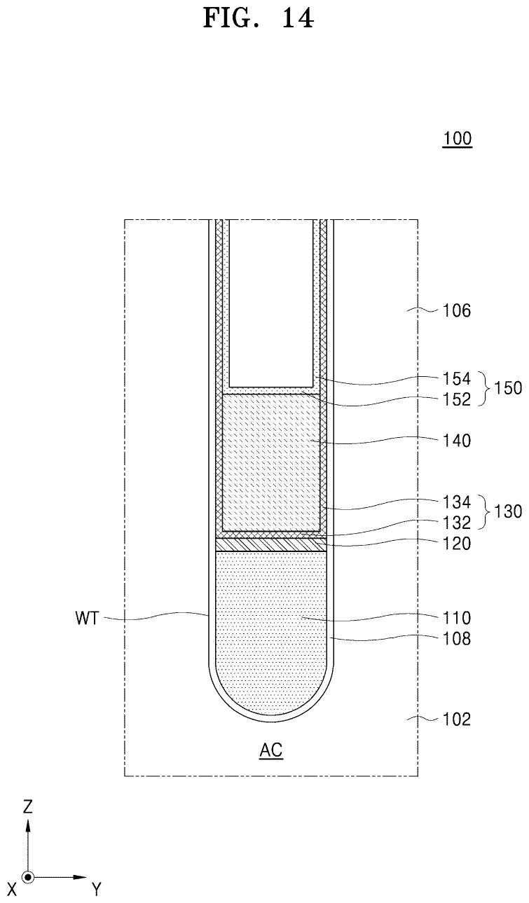

Referring to FIG. 14, the oxide film 150 is formed along the surface of the intermediate insulating film 130, the surface being higher than the upper surface of the second gate pattern 140, and the upper surface of the second gate pattern 140. In embodiments, the oxide film 150 may include silicon oxide.

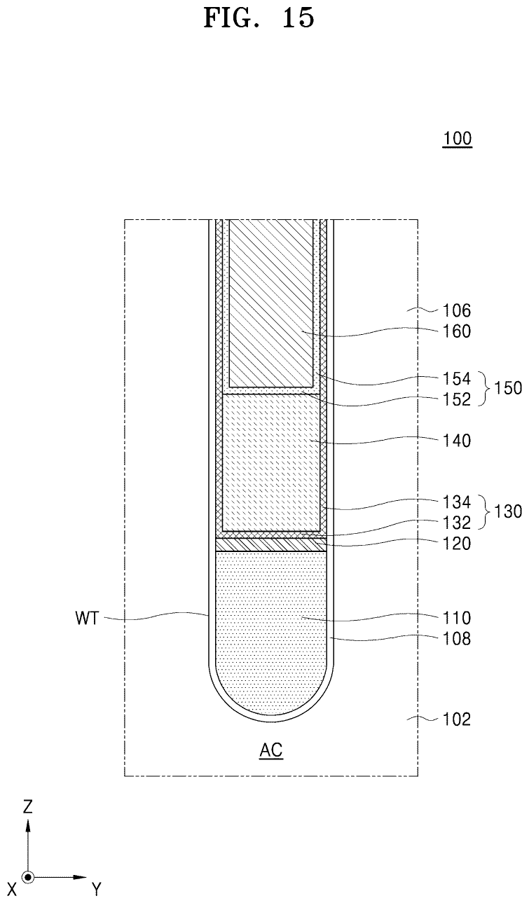

Referring to FIG. 15, the insulating capping pattern 160 is formed to fill the upper region of the word line trench WT on the oxide film 150.

In the above process, a gate structure including the gate insulating film 108, the first gate pattern 110, the interface barrier film 120, the intermediate insulating film 130, the second gate pattern 140, the oxide film 150, and the insulating capping pattern 160 may be formed within the word line trench WT.

Referring back to FIG. 4, impurities may be doped on the substrate 102 to form the pair of source/drain regions 106 on both sides (e.g., opposite sides) of the word line trench WT. In some embodiments, the doping process for forming the pair of source/drain regions 106 may be performed prior to forming the word line trench WT described with reference to FIG. 8.

By performing the above process, the integrated circuit device 100 illustrated in FIG. 4 may be manufactured.

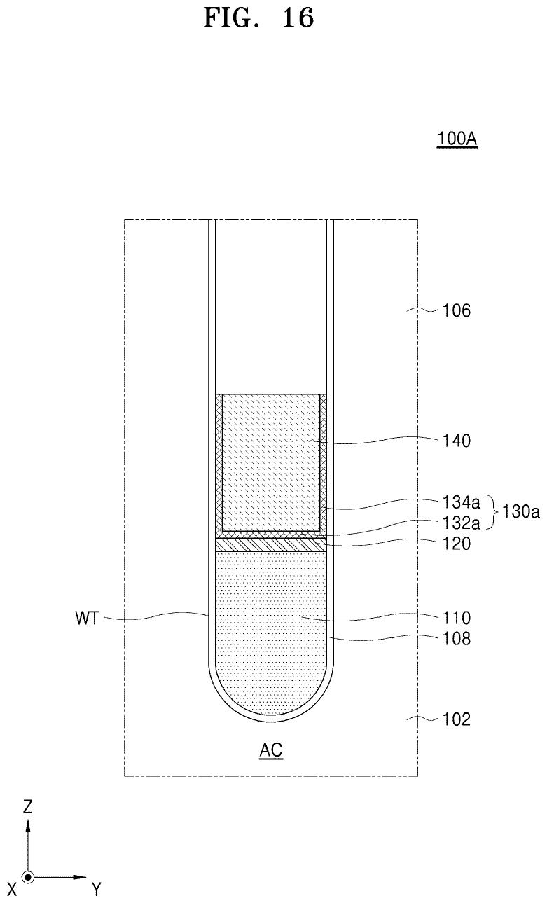

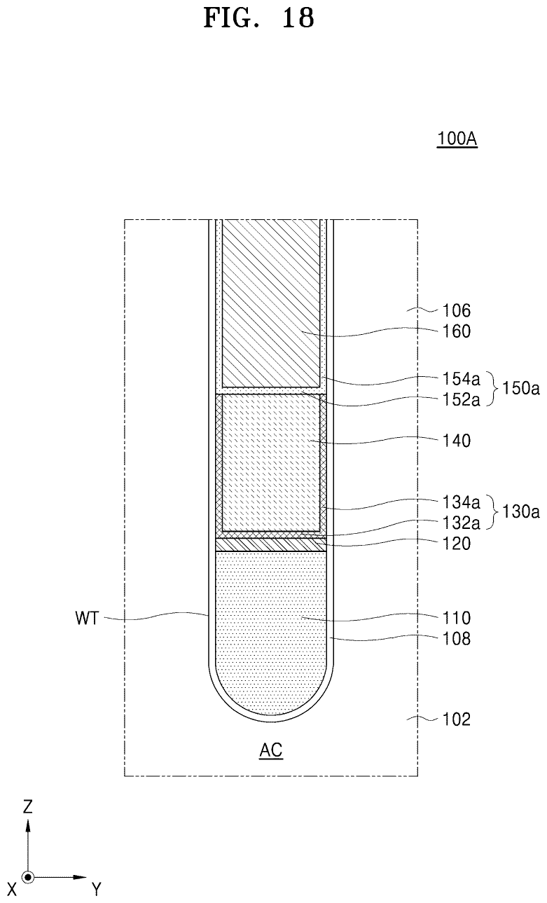

FIGS. 16 to 18 are cross-sectional views illustrating a method of manufacturing an integrated circuit device, according to an embodiment. FIGS. 16 to 18 illustrate a method of manufacturing the integrated circuit device 100A of FIG. 5. FIG. 16 shows a process after the process of FIG. 12.

Referring to FIG. 16, a portion of the second gate film (see 140a of FIG. 12) and a portion of the intermediate insulating film (see 130 of FIG. 12) are removed through an etch back process to form the second gate pattern 140 and the intermediate insulating film 130a.

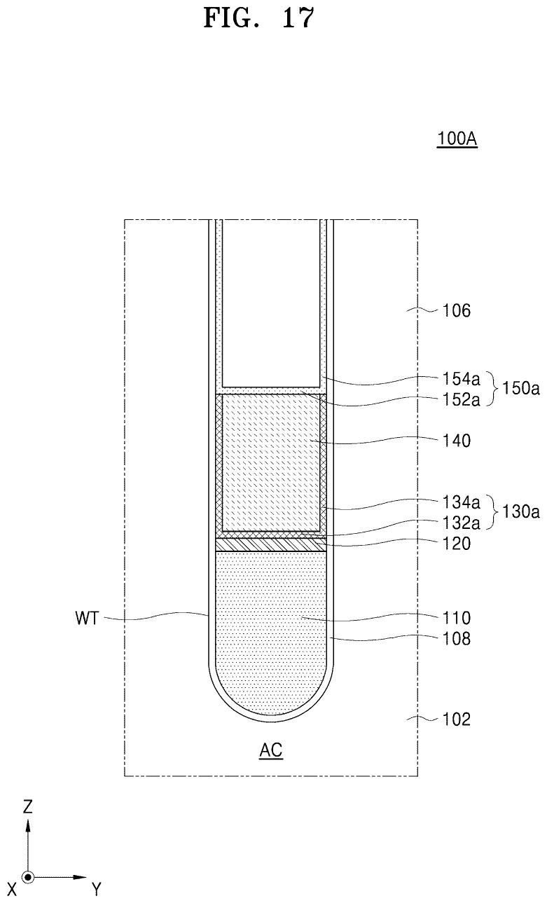

Referring to FIG. 17, the oxide film 150a is formed along the surface of the gate insulating film 108, the surface being higher than the upper surface of the second gate pattern 140, and the upper surface of the second gate pattern 140, and the upper surface of the intermediate insulating film 130a.

Referring to FIG. 15, the insulating capping pattern 160 is formed on the oxide film 150a to fill the upper region of the word line trench WT.

In the above process, a gate structure including the gate insulating film 108, the first gate pattern 110, the interface barrier film 120, the intermediate insulating film 130a, the second gate pattern 140, the oxide film 150a, and the insulating capping pattern 160 may be formed within the word line trench WT. Thereafter, the integrated circuit device 100A of FIG. 5 may be manufactured by forming the pair of source/drain regions 106 on both sides (e.g., opposite sides) of the word line trench WT by doping impurities on the substrate 102.

While the inventive concept has been particularly shown and described with reference to embodiments thereof, it will be understood that various changes in form and details may be made therein without departing from the spirit and scope of the following claims.

What is claimed is:

1. An integrated circuit device comprising:
a substrate having a word line trench formed therein;
a gate insulating film covering an inner surface of the word line trench;
a first gate pattern filling a lower region of the word line trench on the gate insulating film;
an interface barrier film disposed on the first gate pattern;
an intermediate insulating film covering an upper surface of the interface barrier film and a side surface of the gate insulating film, the side surface of the gate insulating film being higher than the upper surface of the interface barrier film relative to a lower surface of the substrate;
a second gate pattern filling a middle region of the word line trench on the intermediate insulating film;
an insulating capping pattern filling an upper region of the word line trench on the second gate pattern; and
an oxide film covering a lower surface and side surfaces of the insulating capping pattern.

2. The integrated circuit device of claim 1, wherein the intermediate insulating film comprises a horizontal extension portion arranged between the upper surface of the interface barrier film and a lower surface of the second gate pattern, and a vertical extension portion arranged on the gate insulating film to be in contact with side surfaces of the second gate pattern, and
the vertical extension portion extends from the upper surface of the interface barrier film to an upper portion of the word line trench, and upper surfaces of the vertical extension portion are disposed on the same plane as an upper surface of the insulating capping pattern.

3. The integrated circuit device of claim 1, wherein the intermediate insulating film comprises a horizontal extension portion arranged between the upper surface of the interface barrier film and a lower surface of the second gate pattern, and a vertical extension portion arranged on the gate insulating film to be in contact with side surfaces of the second gate pattern, and
upper surfaces of the vertical extension portion are arranged on a same plane as an upper surface of the second gate pattern.

4. The integrated circuit device of claim 1, wherein the oxide film comprises a first portion arranged between the upper surface of the second gate pattern and the lower surface of the insulating capping pattern, and a second portion extending vertically along side surfaces of the insulating capping pattern, and
an upper surface of the second portion is arranged on a same plane as the upper surface of the insulating capping pattern.

5. The integrated circuit device of claim 1, wherein the intermediate insulating film comprises ZnO, Al₂O₃, or TiO₂.

6. The integrated circuit device of claim 1, wherein the intermediate insulating film is conformally formed on the interface barrier film and the gate insulating film, and
a thickness of the intermediate insulating film is between 5 Å and 30 Å.

7. The integrated circuit device of claim 1, wherein a thickness of the oxide film is between 5 Å and 40 Å.

8. The integrated circuit device of claim 1, wherein the first gate pattern comprises a metal or a conductive metal nitride, and
the second gate pattern comprises polysilicon.

9. The integrated circuit device of claim 1, wherein the interface barrier film comprises a nitride of a metal material included in the first gate pattern.

10. The integrated circuit device of claim 1, wherein the oxide film comprises silicon oxide.

11. An integrated circuit device comprising:
a substrate having a word line trench formed therein;
a gate insulating film covering an inner surface of the word line trench;
a first gate pattern filling a lower region of the word line trench on the gate insulating film;
an interface barrier film disposed on the first gate pattern;
an intermediate insulating film covering an upper surface of the interface barrier film and a side surface of the gate insulating film, the side surface of the gate insulating film being higher than the upper surface of the interface barrier film relative to a lower surface of the substrate;
a second gate pattern filling a middle region of the word line trench on the intermediate insulating film;
an insulating capping pattern filling an upper region of the word line trench on the second gate pattern; and
an oxide film disposed between the insulating capping pattern and the second gate pattern.

12. The integrated circuit device of claim 11, wherein the intermediate insulating film comprises a horizontal extension portion arranged between the upper surface of the interface barrier film and a lower surface of the second gate pattern, and a vertical extension portion arranged on the gate insulating film to be in contact with side surfaces of the second gate pattern, and
the vertical extension portion extend from the upper surface of the interface barrier film to an upper portion of the word line trench, and upper surfaces of the vertical extension portion are disposed on the same plane as the upper surface of the insulating capping pattern.

13. The integrated circuit device of claim 11, wherein the intermediate insulating film comprises a horizontal extension portion arranged between the upper surface of the interface barrier film and a lower surface of the second gate pattern, and a vertical extension portion arranged on the gate insulating film to be in contact with side surfaces of the second gate pattern, and
upper surfaces of the vertical extension portion are arranged on a same plane as an upper surface of the second gate pattern.

14. The integrated circuit device of claim 11, wherein the intermediate insulating film comprises ZnO, Al₂O₃, or TiO₂.

15. The integrated circuit device of claim 11, wherein the intermediate insulating film is conformally formed on the interface barrier film and the gate insulating film, and
a thickness of the intermediate insulating film is between 5 Å and 30 Å.

16. The integrated circuit device of claim 11, wherein a thickness of the oxide film is 5 Å between 40 Å.

17. The integrated circuit device of claim 11, wherein the first gate pattern comprises a metal or a conductive metal nitride, and
the second gate pattern comprises polysilicon.

18. The integrated circuit device of claim 11, wherein the interface barrier film comprises a nitride of a metal material included in the first gate pattern.

19. The integrated circuit device of claim 11, wherein the oxide film comprises silicon oxide.

20. An integrated circuit device comprising:
a substrate having a word line trench formed therein;
a gate insulating film covering an inner surface of the word line trench;
a first gate pattern filling a lower region of the word line trench on the gate insulating film;
an interface barrier film disposed on the first gate pattern;
an intermediate insulating film covering an upper surface of the interface barrier film and a side surface of the gate insulating film, the side surface of the gate insulating film being higher than the upper surface of the interface barrier film relative to a lower surface of the substrate;
a second gate pattern filling a middle region of the word line trench on the intermediate insulating film;
an insulating capping pattern filling an upper region of the word line trench on the second gate pattern;
an oxide film covering a lower surface and side surfaces of the insulating capping pattern; and
a pair of source/drain regions formed outside the word line trench on opposite sides of the word line trench,
wherein the intermediate insulating film comprises a horizontal extension portion arranged between the upper surface of the interface barrier film and a lower surface of the second gate pattern, and a vertical extension portion arranged on the gate insulating film to be in contact with side surfaces of the second gate pattern,
the vertical extension portion extends from the upper surface of the interface barrier film to an upper portion of the word line trench, and upper surfaces of the vertical extension portion are disposed on a same plane as an upper surface of the insulating capping pattern,
the oxide film comprises a first portion arranged between an upper surface of the second gate pattern and the lower surface of the insulating capping pattern, and a second portion extending vertically along the side surfaces of the insulating capping pattern,
an upper surface of the second portion is arranged on the same plane as the upper surface of the insulating capping pattern,
the first gate pattern comprises a metal or a conductive metal nitride,
the second gate pattern comprises polysilicon,
the interface barrier film comprises a nitride of a metal material included in the first gate pattern, and
a lower surface of the pair of source/drain regions are arranged higher than an upper surface of the second gate pattern relative to the lower surface of the substrate.
